(19) United States
(12) Patent Application Publication
(10) Pub. No.: US 2010/0300523 A1
(43) Pub. Date: Dec. 2, 2010

(54) DYE-SENSITIZED SOLAR CELL AND METHOD OF FABRICATING THE SAME

(75) Inventors: Hogyeong Yun, Seoul (KR); Mangu Kang, Daejeon (KR); Hunkyun Pak, Daejeon (KR); ZinSig Kim, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/769,730

(22) Filed: Apr. 29, 2010

(30) Foreign Application Priority Data
Jun. 1, 2009 (KR) 10-2009-0048090
Aug. 28, 2009 (KR) 10-2009-0080505

(51) Int. Cl. H01L 31/04; H01L 31/18

(52) U.S. Cl. 136/256; 438/72; 257/E31.119; 257/E31.129

(57) ABSTRACT

Provided are dye-sensitized solar cells in which a transparent conductive oxide is not used as a light receiving substrate and methods of fabricating the same. The dye-sensitized solar cell includes an upper electrode layer, which is disposed between a lower electrode layer and a photovoltaic conversion part and has through-holes, and a supporter disposed between the lower electrode layer and the light receiving substrate. The supporter may be a pore layer.

### CROSS-REFERENCE TO RELATED APPLICATIONS

This U.S. non-provisional patent application claims priority under 35 U.S.C. §119 of Korean Patent Application Nos. 10-2009-0048090, filed on Jun. 1, 2009, and 10-2009-0080505, filed on Aug. 28, 2009, the entire contents of which are hereby incorporated by reference.

### BACKGROUND OF THE INVENTION

The present disclosure herein relates to a solar cell, and more particularly, to a dye-sensitized solar cell and a method of fabricating the same.

Solar cells are photovoltaic energy conversion systems that convert light energy radiated from the sun into electrical energy. Silicon solar cells, which are mainly used at present, employ a p-n junction diode formed within silicon for photovoltaic energy conversion. However, to prevent premature recombination of electrons and holes, the silicon should have a high degree of purity and less defects. Since these technical requirements cause an increase in material cost, silicon solar cells have a high fabrication cost per watt.

In addition, since only photons, which have energy greater than a bandgap, contribute to generating current, silicon used for silicon solar cells is doped to have a lower bandgap. However, due to the lowered bandgap, electrons excited by blue light or ultraviolet light become overly energized and are consumed to generate heat rather than electrical current. Also, a p-type layer should be sufficiently thick to increase photon capturing probability. However, since the thick p-type layer increases the probability of excited electrons recombining with holes before they reach a p-n junction, the efficiency of silicon solar cells remains low in an approximate range of about 7% to about 15%.

In 1991, Michael Gratzel, Mohammad K. Nazeeruddin, and Brian O'Regan disclosed a Dye-sensitized Solar Cell (DSC), based on the photosynthesis reaction principle, and known as the “Gratzel cell”. A dye-sensitized solar cell, which employs the Gratzel model as a prototype, is a photoelectrochemical system that employs a dye material and a transition metal oxide layer instead of a p-n junction diode for photovoltaic energy conversion. Since the material used in such a dye-sensitized solar cell is inexpensive and the fabrication method is simple, fabrication costs of the dye-sensitized solar cells are lower than those of silicon solar cells. Accordingly, in case where energy conversion efficiency of the dye-sensitized solar cell increases, it has a lower fabrication cost per output watt than a silicon solar cell.

### SUMMARY OF THE INVENTION

Embodiments of the inventive concept provide a dye-sensitized solar cell capable of reducing fabrication costs thereof.

Embodiments of the inventive concept also provide a dye-sensitized solar cell capable of increasing transmittance of incident light.

Embodiments of the inventive concept also provide a method of fabricating a dye-sensitized solar cell capable of reducing fabrication costs thereof.

Embodiments of the inventive concept also provide a method of fabricating a dye-sensitized solar cell capable of increasing transmittance of incident light.

Embodiments of the inventive concept provide dye-sensitized solar cells in which a transparent conductive oxide is not used as a light receiving substrate. The dye-sensitized solar cells include: a photovoltaic conversion part disposed between a lower electrode layer and a light receiving substrate; an upper electrode layer having through-holes, the upper electrode layer being disposed between the lower electrode layer and the photovoltaic conversion part; a catalytic layer covering a top surface of the lower electrode layer, the catalytic layer being disposed between the lower and upper electrode layers; and an electrolyte solution disposed between the catalytic layer and the light receiving substrate. At this time, a supporter is disposed between the lower electrode layer and the light receiving substrate. The supporter includes a pore insulation layer, and the electrolytic solution is impregnated into the supporter.

In some embodiments, the supporter may be disposed between the catalytic layer and the upper electrode layer, between the upper electrode layer and the light receiving substrate, or between the catalytic layer and the upper electrode layer and between the upper electrode layer and the light receiving substrate.

In other embodiments, the light receiving substrate may be formed of a non-conductive transparent material, and the photovoltaic conversion part may include a plurality of semiconductor particles and a plurality of dye materials attached to a surface of each of the semiconductor particles. According to an embodiment, the photovoltaic conversion part may be spaced from the light receiving substrate. Also, the entire top and lower surfaces of the upper electrode layer may be substantially flat, and the through-holes may be regularly arranged within the upper electrode layer.

In other embodiments of the inventive concept, methods of fabricating a dye-sensitized solar cell in which a transparent conductive oxide is not used as a light receiving substrate. The methods include: preparing an upper electrode layer in which through-holes are defined; disposing the upper electrode layer having the through-holes on a lower electrode layer; forming a photovoltaic conversion part on the upper electrode layer; forming a supporter between the lower electrode layer and the light receiving substrate; and impregnating an electrolyte solution into the supporter. At this time, the supporter may include a pore insulation layer.

In some embodiments, the supporter may be disposed between the catalytic layer and the upper electrode layer, between the upper electrode layer and the light receiving substrate, or between the catalytic layer and the upper electrode layer and between the upper electrode layer and the light receiving substrate.

In other embodiments, the through-holes may be formed in the upper electrode layer before the upper electrode layer is attached on the lower electrode layer, and the light receiving substrate may be formed of a non-conductive transparent material. The lower electrode layer and the upper electrode layer may include metal films, respectively, and the photovoltaic conversion part may include a plurality of semiconductor particles and a plurality of dye materials attached to a surface of each of the semiconductor particles.

In still other embodiments, the methods may include forming a catalytic layer on a top surface of the lower electrode layer before the upper electrode layer is attached on the lower electrode layer; forming a lower sealant spacing the upper electrode layer from the lower electrode layer on an edge of a top surface of the catalytic layer; and forming an upper sealant spacing the light receiving substrate from the upper electrode layer on an edge of a top surface of the upper electrode layer.

In even other embodiments, the preparing of the upper electrode layer having the through-holes may include patterning the metal film using an etching mask. At this time, the etching mask may have openings defining positions at which the through-holes are formed, and the openings may be spatially regally arranged.

In yet other embodiments, the attaching of the upper electrode layer on the lower electrode layer may be performed using a roll-to-roll process.

### BRIEF DESCRIPTION OF THE FIGURES

The accompanying figures are included to provide a further understanding of the inventive concept, and are incorporated in and constitute a part of this specification. The drawings illustrate exemplary embodiments of the inventive concept and, together with the description, serve to explain principles of the inventive concept. In the figures:

FIG. 1 is a sectional view of a dye-sensitized solar cell according to an embodiment of the inventive concept;

FIG. 2 is a sectional view of a dye-sensitized solar cell having a having a flexible property according to an embodiment of the inventive concept;

FIGS. 3A and 3B are perspective view of an upper electrode layer according to embodiments of the inventive concept;

FIG. 4 is a view illustrating a process of forming an upper electrode layer according to an embodiment of the inventive concept;

FIGS. 5 through 9 are sectional views of a dye-sensitized solar cell according to other embodiments of the inventive concept;

FIG. 10 is a flowchart illustrating a process of fabricating a dye-sensitized solar cell according to an embodiment of the inventive concept;

FIG. 11 is a flowchart illustrating a process of fabricating a dye-sensitized solar cell according to another embodiment of the inventive concept; and

FIG. 12 is s flowchart illustrating a process of fabricating a dye-sensitized solar cell according to another embodiment of the inventive concept.

### DETAILED DESCRIPTION OF PREFERRED EMBODIMENTS

Preferred embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

In the figures, it will be understood that when a layer (or film) is referred to as being ‘on’ another layer or substrate, it can be directly on the other layer or substrate, or intervening layers may also be present. Further, it will be understood that the dimensions of layers and regions are exaggerated for clarity of illustration. In addition, in various embodiments of the inventive concept, while terms such as “first”, “second”, and “third” are used to describe various regions, layers, etc., these regions, layers, etc. should not restricted by said terms. The terms are used solely to differentiate one particular region or layer from another region or layer. Therefore, a layer referred to as a first layer in one embodiment may be referred to as a second layer in another embodiment. The respective embodiments described and exemplified herein include complementary embodiments thereof.

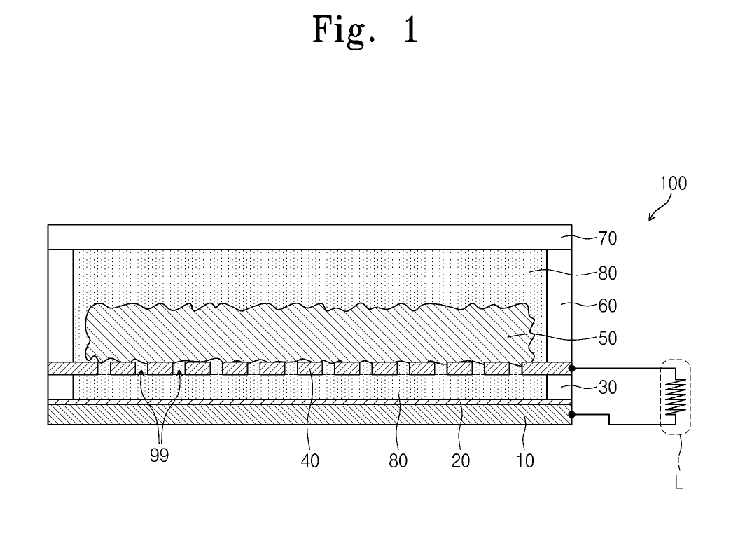

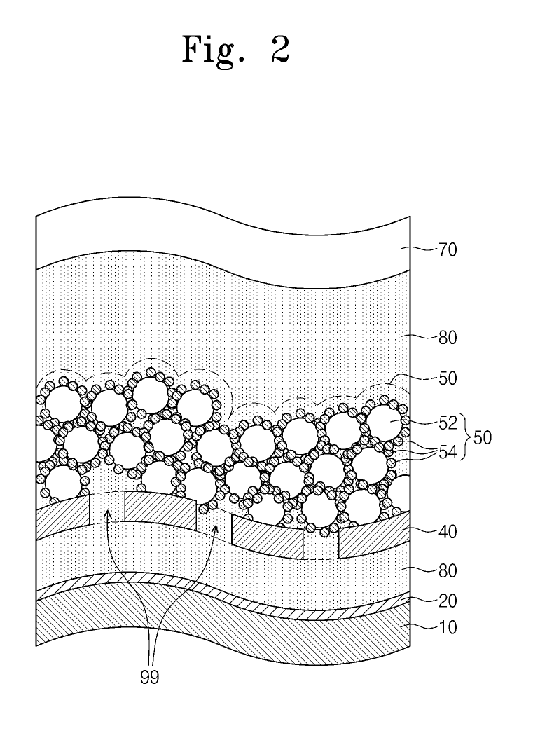

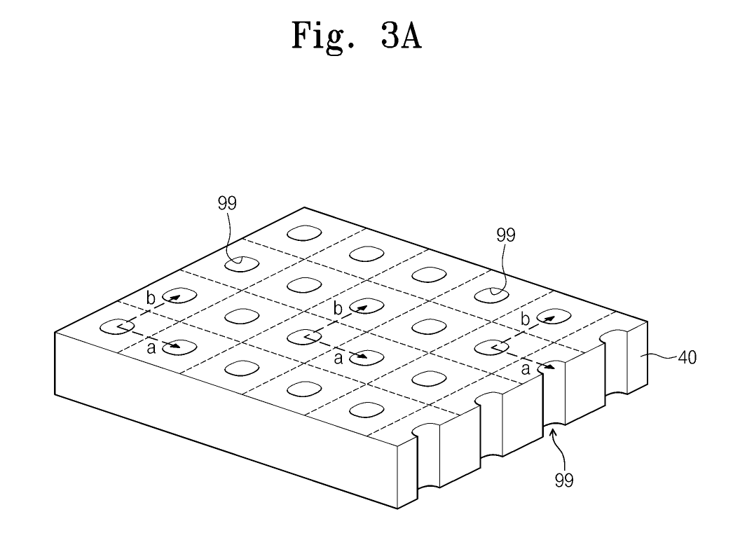

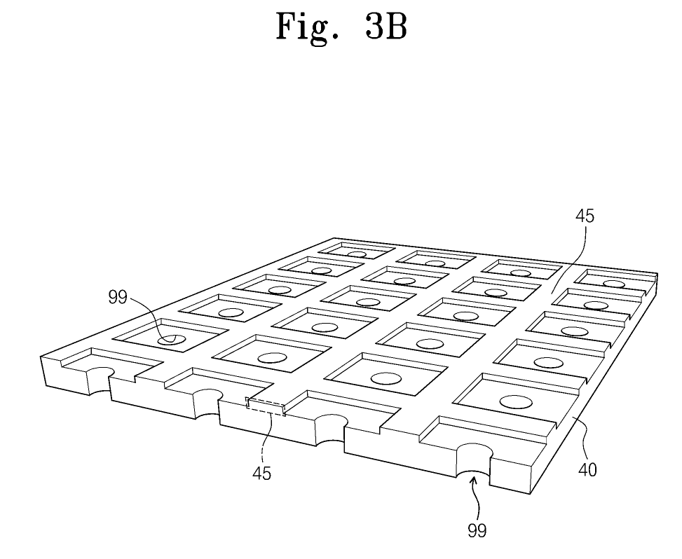

FIG. 1 is a sectional view of a dye-sensitized solar cell according to an embodiment of the inventive concept, FIG. 2 is a sectional view of a dye-sensitized solar cell having a flexible property according to an embodiment of the inventive concept, and FIGS. 3A and 3B are perspective view of an upper electrode layer according to embodiments of the inventive concept.

Referring to FIG. 1, a dye-sensitized solar cell 100 according to embodiments of the inventive concept includes a lower electrode layer 10, a light receiving substrate 70 disposed on the lower electrode layer 10, a photovoltaic conversion part 50 disposed between the lower electrode layer 10 and the light receiving substrate 70, and an upper electrode layer 40 disposed between the photovoltaic conversion part 50 and the lower electrode layer 10. In addition, a catalytic layer 20 spaced from the upper electrode layer 40 is disposed on a top surface of the lower electrode layer 10. An electrolyte solution is filled into a space between the catalytic layer 20 and the light receiving substrate 70.

The photovoltaic conversion part 50 may includes a semiconductor material and a dye absorbed on a surface of the semiconductor material. According to an embodiment, as shown in FIG. 2, the photovoltaic conversion part 50 may include oxide semiconductor particles 52 and dye materials 54 absorbed on surfaces of the oxide semiconductor particles 52. The oxide semiconductor particles 52 may be formed of one of metal oxides including transition metal oxides such as titanium oxide (TiO₂), tin oxide (SnO₂), zirconium oxide (ZrO₂), silicon oxide (SiO₂), magnesium oxide (MgO), neobium oxide (Nb₂O₅), and zinc oxide (ZnO). The dye materials 54 may be dye molecules such as a ruthenium complex that can convert light energy into electrical energy. For example, the dye materials 54 may include N719 (Ru(dcbpy)2(NCS)2 containing 2 protons). Alternatively, the dye materials 54 may include at least one of well-known various dyes such as N712, Z907, Z910, and K19.

The dye-sensitized solar cell 100 according to embodiments of the inventive concept may have a flexible property. That is, as shown in FIG. 2, the dye-sensitized solar cell may be normally operated without losing its functions or being broken under an external force capable of deforming an outer appearance of a product. According to these embodiments, the light receiving substrate 70, the lower electrode layer 10, and the upper electrode layer 40 may have thicknesses and materials, which may provide the flexible property.

Particularly, the lower electrode layer 10 and the upper electrode layer 40 may be respectively formed of a thin film or foil including at least one of metals and metal alloys. For example, the lower electrode layer 10 and the upper electrode layer 40 may be formed of titanium, stainless steel, aluminium, and copper according to kinds of the products, but is not limited thereto. That is, the lower electrode layer 10 and the upper electrode layer 40 may be formed of various metallic materials. According to a modified embodiment, a bottom surface of the lower electrode layer 10 may be coated with an insulative thin film (not shown). Also, the lower electrode layer 10 and the upper electrode layer 40 may respectively have thicknesses ranging from several micrometers to several millimeters to provide the flexible property. A specific thickness thereof may be changed according kinds of corresponding materials.

According to embodiments of the inventive concept, the light receiving substrate 70 may be formed of only a transparent material without a transparent conductive oxide (TCO). For example, the light receiving substrate 70 may be formed of a glass or polymer film. As well-known, the transparent substrate containing the TOC may provide conductivity. However, since its fabrication costs are expensive, the dye-sensitized solar cell that does not use the transparent substrate containing the TOC may be fabricated at relatively low costs. According to an embodiment, the light receiving substrate 70 may include a transparent plastic film having the flexible property.

The electrolyte solution 80 may include a redox iodide electrolyte. According to an embodiment of the inventive concept, the electrolyte solution 80 may include an electrolyte of I₃⁻/I⁻ obtained by dissolving 0.7 M 1-vinyl-3-hexyl-imidazolium iodide, 0.1 M LiI, and 40 mM I2(Iodine) in 3-methoxypropionitrile. According to another embodiment of the inventive concept, the electrolyte solution 80 may include an acetonitrile electrolyte containing 0.6 M butylmethylimidazolium, 0.02 M I₂, 0.1 M guanidinium thiocyanate, and 0.5 M 4-tert-butylpyridine. However, one of various electrolytes not exemplarily mentioned above may be used as the electrolyte for dye-sensitized solar cell according to the inventive concept. For example, the electrolyte solution 80 may include alkylimidazolium iodides or tetra-alkyl ammoniumiodides. The electrolyte solution 80 may further include tert-butylpyridin (TBP), benzimidazole (BI), and N-Methylbenzimidazole (NMBI) as surface additives, and may use acetonitrile, propionitrile, or a mixed liquid of acetonitrile and valeronitrile as a solvent.

The catalytic layer 20 contacts the electrolyte solution 80 to participate in a reducing process of an electrolyte. According to an embodiment, when the electrolyte solution 80 is a redox iodide electrolyte solution, the catalytic layer 20 may be platinum (Pt) coated on the lower electrode layer 10.

When sunlight is incident into the photovoltaic conversion part 50 through the light receiving substrate 70, electrons within the dye materials 54 are excited by the incident light and injected into a conduction band of the oxide semiconductor particles 52. Thereafter, the electrons are reduced in the electrolyte solution 80 via the upper electrode layer 40, a predetermined load L, and the lower electrode layer 10. This process may be called an electron circulation system of the dye-sensitized solar cell.

To continuously realize the reducing process of the electrolyte or the electron circulation system of the dye-sensitized solar cell, ions that lose the electrons in the photovoltaic conversion part 50 should be diffused into the catalytic layer 20 in which the reducing process occurs. For this, according to embodiments of the inventive concept, as shown in FIGS. 1 through 3, at least one or more through-holes 99 through which the ions pass may be defined in the upper electrode layer 40 disposed between the photovoltaic conversion part 50 and the catalytic layer 20.

According to an embodiment, the through-holes 99 may be regularly arranged within a predetermined region of the upper electrode layer 40. Particularly, a relative position and distance between a certain through-hole and through-holes adjacent to the certain through-hole may be expressed by two vectors a and b, which are not parallel to each other. Also, a relative position and distance between other through-holes adjacent to each other may be expressed by the two vectors a and b in the same way. As such, when the through-holes 99 are regularly arranged within the upper electrode layer 40, the ions may be uniformly diffused into the catalytic layer 20. As a result, the reducing process may be uniformly efficiently performed, and thus, the photovoltaic performance of the products may be improved.

According to another embodiment of the inventive concept, an arrangement of the whole through-holes 99 defined within the upper electrode layer 40 may be substantially completely expressed by a plurality of vector sets including a vector set consisting of predetermined vectors. When the number of the vector sets that define the arrangement of the through-holes 99 increases, the through-holes 99 may be irregularly and randomly arranged. That is, according to an embodiment of the inventive concept, a regulation of the arrangement of the through-holes 99 may be variously changed. The respective through-holes 99 may have a width less than an average diameter of the oxide semiconductor particles 52 or several times greater than the average diameter of the oxide semiconductor particles 52. For example, the respective through-hole 99 may have a width ranging from several micrometers to several millimeters. According to an embodiment, the width of the through-holes 99 may be defined such that the oxide semiconductor particles 52 effectively block the through-holes 99.

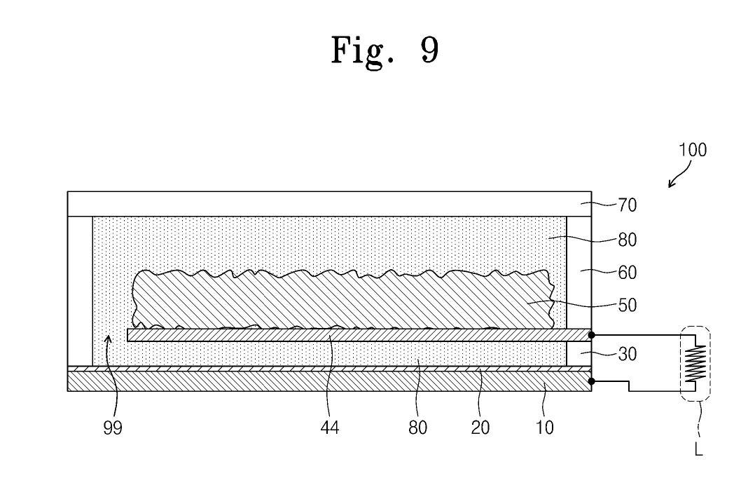

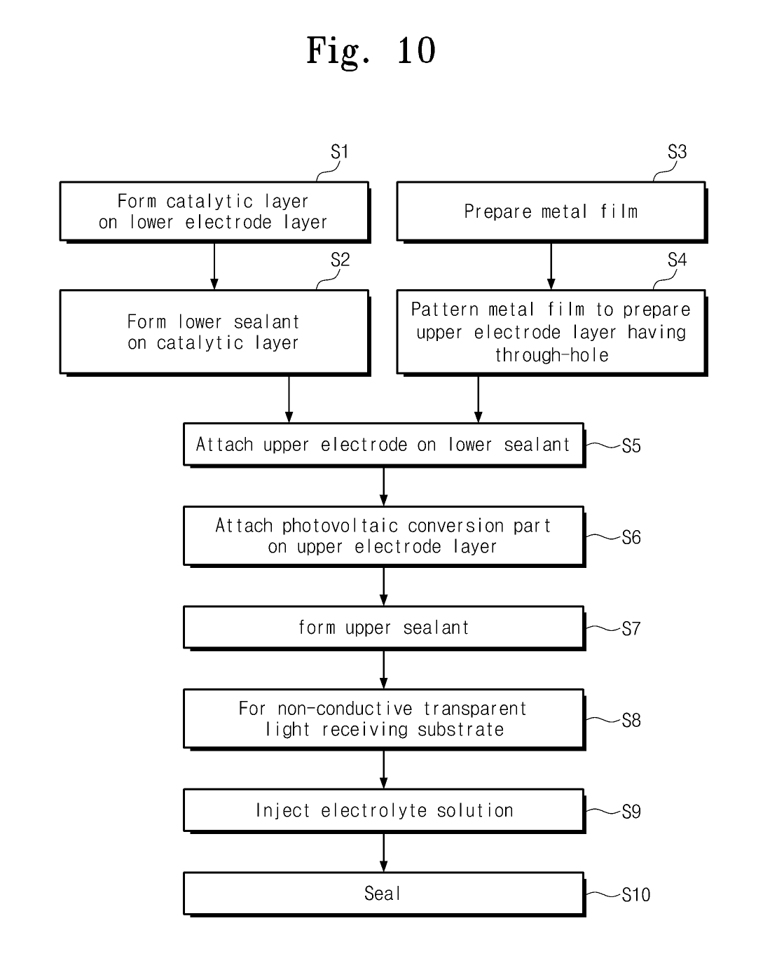

With respect to the thickness of the upper electrode layer 40, according to an embodiment of the inventive concept, as shown in FIGS. 1, 2, 3A, and 4 through 9, the upper electrode layer 40 may have a substantially uniform thickness in an entire region except the through-holes 99. According to another embodiment of the inventive concept, as shown in FIG. 3B, the upper electrode layer 40 may include at least one protrusion 45 extending from a top surface thereof. However, the protrusion 45 may be variously varied in the embodiment described with reference to FIG. 3B. For example, the protrusion 45 may include at least one of a portion extending downwardly from a bottom surface of the upper electrode layer 40 and a portion extending upwardly from a top surface of the upper electrode layer 40. Also, the protrusion 45 may be variously changed in position and thickness.

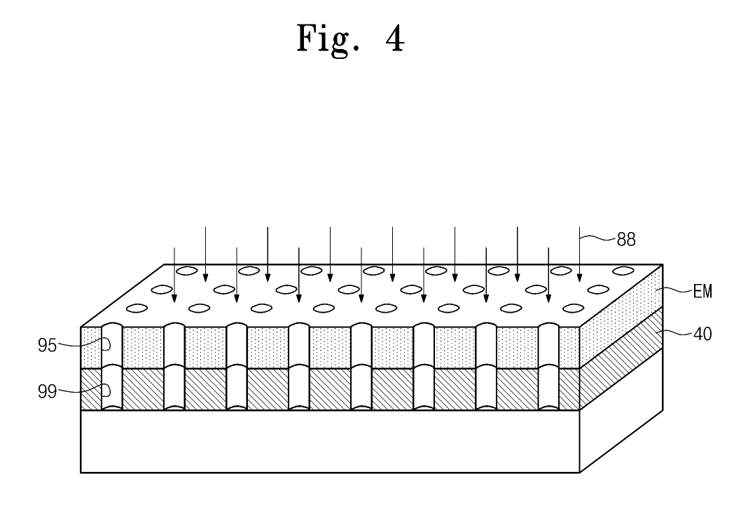

Referring to FIG. 4, a method of forming the through-holes 99 in the upper electrode layer 40 may include etching 88 a metal film for the upper metal layer 40 using a predetermined etching mask EM. The etching mask EM may be formed of a recyclable material (e.g., polymer or ceramic). Openings 95 for defining the positions of the through-holes 99 may be defined in the etching mask EM. Since the recyclable etching mask is used, a cost for preparing the upper electrode layer 40 having the through-holes 99 may be reduced, as well as, the through-holes 99 may be defined at the substantially same position in all of the fabricated dye-sensitized solar cells. That is, a positional variation of the through-holes 99 can be reduced. Hence, the fabricated dye-sensitized solar cells can have improved uniformity in product properties.

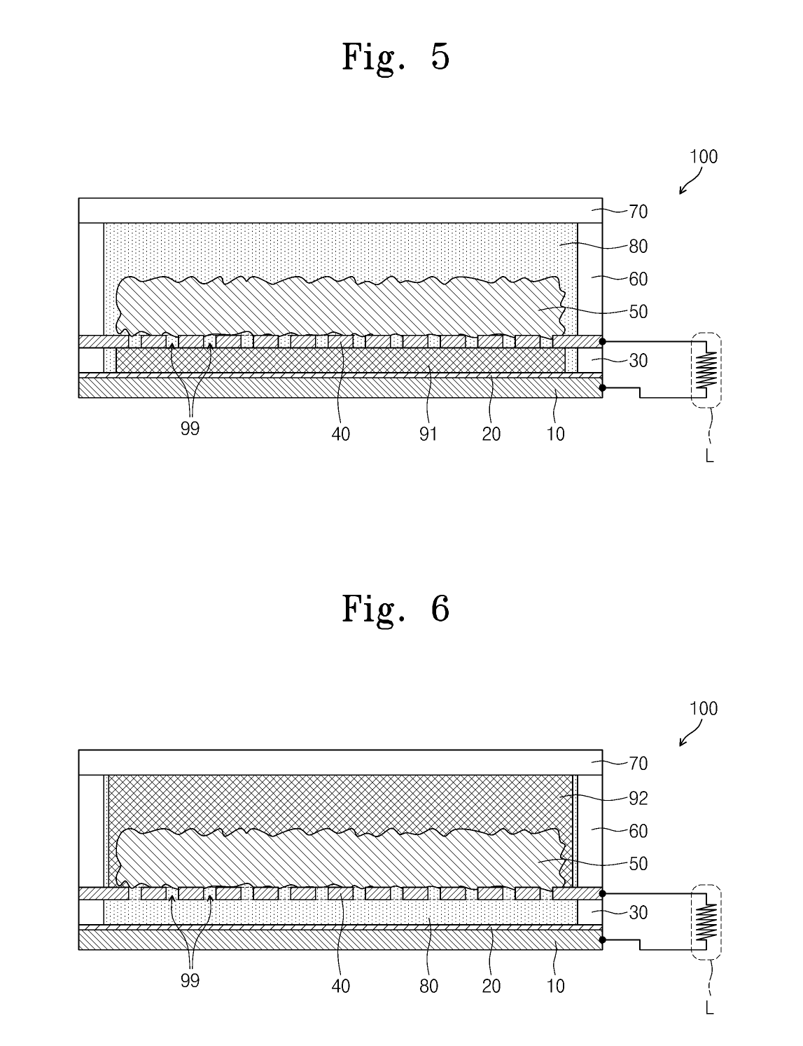

FIGS. 5 through 9 are sectional views of a dye-sensitized solar cell according to other embodiments of the inventive concept. For brief descriptions, the technical features overlapping with the embodiments described with reference to FIG. 1 will be omitted.

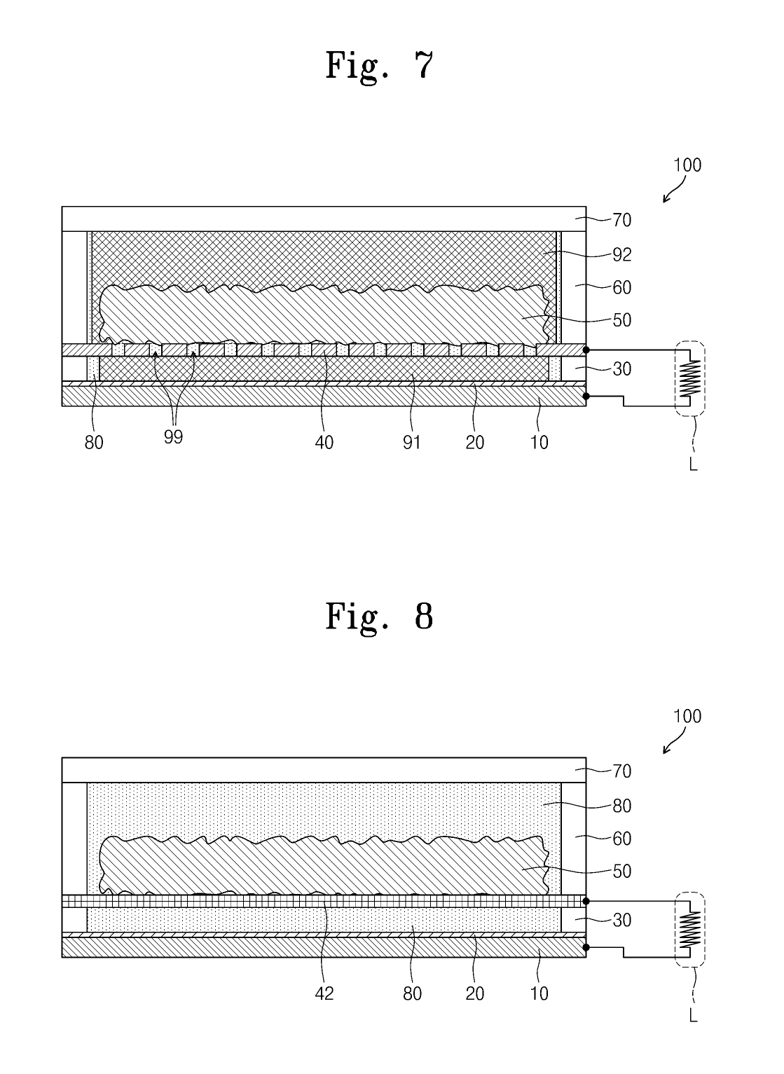

Referring to FIGS. 5 through 7, supporters 91 and 92 may be further disposed between a light receiving substrate 70 and a catalytic layer 20. Specifically, the lower supporter 91 may be disposed between the catalytic layer 20 and an upper electrode layer 40 as shown in FIGS. 5 and 7, or the upper supporter 92 may be disposed between the upper electrode layer 40 and the light receiving substrate 70 as shown in FIGS. 6 and 7. According to these embodiments, respective through-holes 99 may have a width ranging from several micrometers to several millimeters.

According to an embodiment of the inventive concept, the lower supporter 91 may be a spacer that physically/electrically spaces the upper electrode layer 40 from the catalytic layer 20. The lower supporter 91 may be formed of an insulative material (e.g., glass, ceramic, and plastic). The lower supporter 91 may have a ball shape or a bar shape, the inventive concept is not limited thereto. The lower supporter 91 may be variously changed in material and shape. The insulative lower supporter 91 may prevent the catalytic layer 20 and the upper electrode layer 40 from directly contacting (i.e., electrical short) each other. Thus, a gap between the catalytic layer 20 and the upper electrode layer 40 may be maintained. Therefore, it may prevent the product from being damaged by the electrical short even through an external force is applied to the light receiving substrate 70 or the lower electrode layer 10.

According to another embodiment of the inventive concept, the lower or upper supporter 91 or 92 may be formed of a pore insulation material. For example, the lower or upper supporter 91 or 92 may include a polymer or ceramic having fine pores (not shown). According to these embodiments, the electrolyte solution 80 fills the pores of the lower and upper supporters 91 and 92 and is disposed between the light receiving substrate 70 and the catalytic layer 20. That is, the electrolyte solution 80 may be impregnated into the lower and upper supporters 91 and 92.

According to an embodiment, the lower supporter 91 is configured to prevent the oxide semiconductor particles 52 from being substantially effectively moved into a space between the upper electrode layer 40 and the catalytic layer 20 or to a top surface of the catalytic layer 20. For example, the respective pores of the lower supporter 91 may have a width substantially less than or equal to that the respective oxide semiconductor particles 52. However, the movement of the oxide semiconductor particles 52 may be dependent on the disposition of the pores and adhesion properties between the oxide semiconductor particles 52. In this sense, the respective pores of the lower supporter 91 according to another embodiment may have a width greater than that of the respective oxide semiconductor particles 52.

According to an embodiment, the pores of the lower supporter 91 may be continuously connected to each other such that the ions that lose the electrons in the photovoltaic conversion part 50 are diffused into the catalytic layer 20 in which the reducing process occurs.

Referring to FIG. 8, according to modified embodiments, the through-holes 99 may be provided by an upper electrode layer 40 having a structure different from that of the embodiment described with reference to FIG. 3. For example, the upper electrode layer 40 may include a mesh structure including intercrossed and woven wires, a sintered structure in which powders are connected to each other, and a pore metallic material.

According to the modified embodiments, a top surface or a bottom surface of the upper electrode layer 40 may not be flat locally. That is, the upper electrode layer 40 may have different thicknesses according to positions thereof. Such non-uniformity in thickness of the upper electrode layer 40 may exist between upper and lower sealants 60 and 30. In this case, when an adhesion property between the upper and lower sealants 60 and 30 and the upper electrode layer 40 is poor, the electrolyte solution 80 may be leaked to the outside. However, according to the embodiments described with reference to FIGS. 1 through 7, the entire top and lower surfaces of the upper electrode layer 40 are flat. Thus, the upper and lower sealants 60 and 30 may firmly adhere to the upper electrode layer 40 to prevent the electrolyte solution 80 from leaking to the outside.

In addition, as shown in FIGS. 1 through 7, the through-holes 99 may not be formed in an edge region of the upper electrode layer 40 disposed between the upper and lower sealants 60 and 30. That is, the edge region of the upper electrode layer 40 may be flat, because the through-holes 99 are not formed in the edge region. In this case, the non-uniform thickness of the upper electrode layer 40, which may occur in the modified embodiments described above, and the resultant leakage of the electrolyte solution 80 may be further prevented.

Also, according to the modified embodiments, to form the fine through-holes in the upper electrode layer 40, a very expensive fabrication technology is required. For example, in case of the mesh structure, to form the fine through-holes, the number of wires constituting the mesh structure significantly increases. In addition, it is difficult to control each of the wires in a weaving process. However, according to the embodiments described with reference to FIGS. 1 through 7, a patterning process for forming the through-holes 99 may include repeatedly using the etching mask EM that may be fabricated at a relatively low price. Thus, according to the embodiments described with reference to FIGS. 1 through 7, it may possible to fabricate the dye-sensitized solar cell without the TCO (TCO-less DSC) at a low cost.

According to a modified embodiment, the upper electrode layer 40 may be a conductive layer having nano-sided through-holes or a conductive layer including nanotube providing through-holes. According to the modified embodiment, a very expensive fabrication technology is required also. However, according to the embodiments described with reference to FIGS. 1 through 7, it may possible to fabricate the dye-sensitized solar cell without the TCO (TCO-less DSC) at a relatively low cost when compared to the modified embodiment.

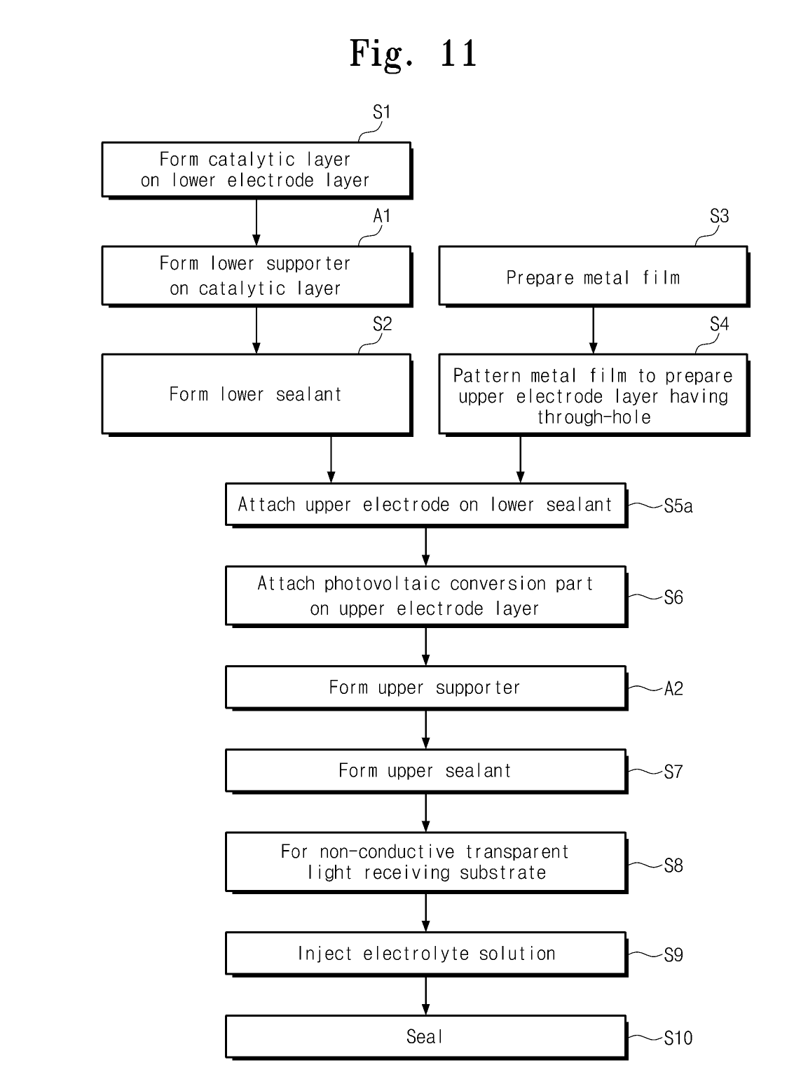

FIG. 10 is a flowchart illustrating a process of fabricating a dye-sensitized solar cell according to an embodiment of the inventive concept.

Referring to FIG. 10, a catalytic layer 20 and a lower sealant 30 are formed on a lower electrode layer 10 in operations S1 and S2, respectively.

According to a process to be performed independently from these processes, a metal film is prepared, and then, a metal film is patterned to prepare an upper electrode layer having at least one through-hole 99 in operations S3 and S4.

In operation S5, the upper electrode layer 40 is attached on the lower sealant 30. In operation S6, a photovoltaic conversion part 50 is formed on the upper electrode layer 40. In operation S7, an upper sealant 60 surrounding the photovoltaic conversion part 50 is formed on the upper electrode layer 40. In operation S8, a non-conductive transparent light receiving substrate 70 is formed on the upper sealant 60. In operation S9, an electrolyte solution 80 is injected between the light receiving substrate 70 and the catalytic layer 20. Thereafter, in operation S10, a sealing process is performed.

According to this embodiment, as shown in FIG. 4, the patterning (S4) of the metal film may include etching 88 the metal film using a predetermined etching mask EM. The etching mask EM may be formed of a recyclable material. Openings 95 for defining positions of the through-holes 99 may be defined in the etching mask EM. Thus, a fabrication cost of a dye-sensitized solar cell may be reduced, as well as, the through-holes 99 may be defined at the substantially same position in all of the fabricated dye-sensitized solar cells. A positional variation of the through-holes 99 may be reduced to improve uniformity in terms of product features of the fabricated dye-sensitized solar cells.

The etching 88 of the metal film may be performed using at least one of an isotopic etching process and an anisotropic etching process. For example, after the etching mask EM is disposed on the metal film, a wet etching process is performed on the metal film to form the through-holes passing through the metal film. When compared to the above-described modified embodiments in which the upper electrode layer 40 is formed as the conductive layer having the nano-sized through holes and including the mesh structure, the sintered structure, and the pore metallic material or the conductive layer including the nanotube providing the through-holes, it may possible to form the upper electrode layer 40 having the through-holes at a low cost by using the etching process.

Since the upper electrode layer 40 is prepared through a process independent from the lower electrode layer 10, the attaching (S5) the upper electrode layer 40 on the lower sealant 30 may be realized using a roll-to-roll process. According to an embodiment of the inventive concept, at least one of the lower electrode layer 10, the catalytic layer 20, the lower sealant 30, the upper sealant 60, and the light receiving substrate 70 may be formed also using the roll-to-roll process. Since the roll-to-roll process does not require a deposition process, the dye-sensitized solar cell according to the inventive concept may be fabricated at a low cost.

According to an embodiment of the inventive concept, the through-holes 99 may not be defined in an edge region of the upper electrode layer 40 disposed between the upper and lower sealants 60 and 30. For this, the etching 88 of the metal film may be performed to selectively/locally etch the metal film in regions in which the photovoltaic conversion part 50 is formed. In this case, as above-described, the non-uniform thickness of the upper electrode layer 40 and the resultant leakage of the electrolyte solution 80 may be effectively prevented.

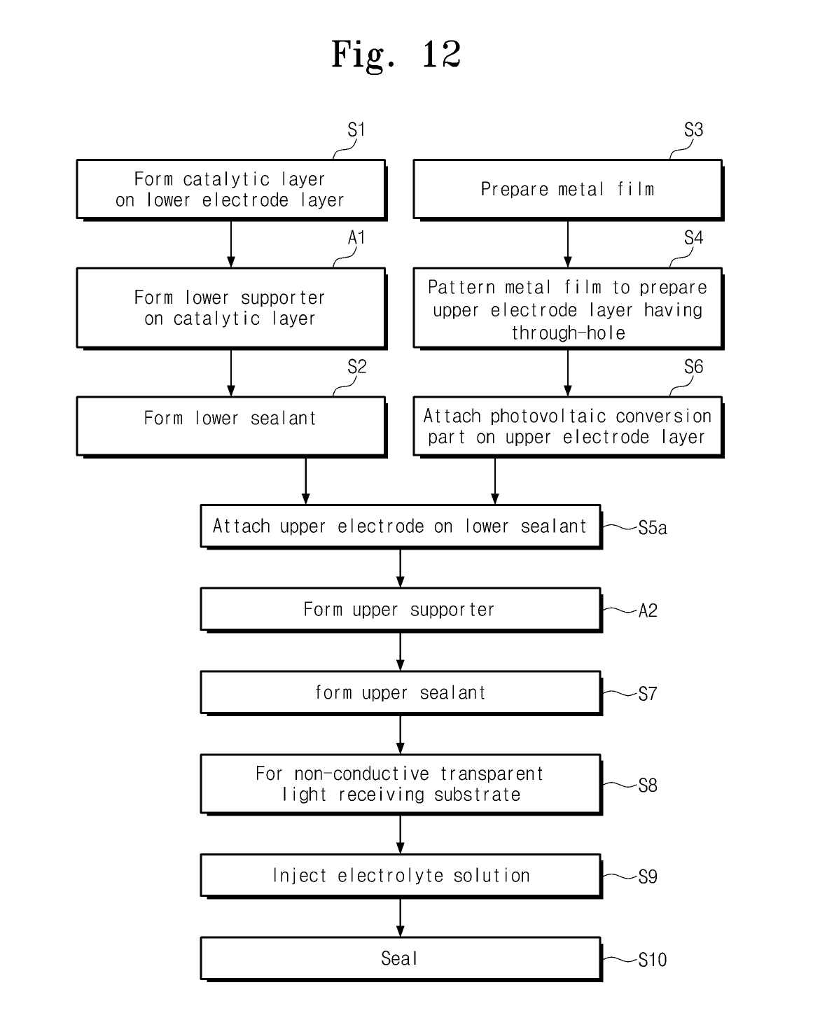

FIG. 11 is a flowchart illustrating a process of fabricating a dye-sensitized solar cell according to another embodiment of the inventive concept. For brief descriptions, the technical features overlapping with the embodiments described with reference to FIG. 10 will be omitted.

Referring to FIG. 11, a fabricating method according to an embodiment may further include forming A1 a lower supporter 91 on the catalytic layer 20 before the upper electrode layer 40 is attached on the lower sealant 30 in operation S5. As a result, as shown in FIGS. 5 and 7, the lower supporter 91 is disposed between the catalytic layer 20 and the upper electrode layer 40. As above-described, in this case, the lower supporter 91 may prevent the oxide semiconductor particles 52 from being moved into a space between the upper electrode layer 40 and the catalytic layer 20 or maintain a distance between the catalytic layer 20 and the upper electrode layer 40. According to the modified embodiment, as shown in FIG. 11, the fabricating method may further include forming A2 an upper supporter 92 on the photovoltaic conversion part 50 before the light receiving substrate 70 is formed in operation S8.

The lower and upper supporters 91 and 92 may be formed of a pore insulation material (e.g., a polymer or ceramic having fine pores (not shown)). According to these embodiments, the electrolyte solution 80 may be impregnated into the lower and upper supporters 91 and 92 and disposed between the light receiving substrate 70 and the catalytic layer 20. The pores of the lower supporter 91 may be continuously connected to each other such that the ions that lose the electrons in the photovoltaic conversion part 50 are diffused into the catalytic layer 20 in which the reducing process occurs.

Referring to FIG. 12, according to another embodiment of the inventive concept, forming the photovoltaic conversion part 50 on the upper electrode layer 40 may be performed before the upper electrode layer 40 is attached on the lower sealant 30. Such a change of the formation sequence may be identically applicable to the embodiment described with reference to FIG. 10.

In the dye-sensitized solar cell according to the embodiments of the inventive concept, the light receiving substrate that does not include the transparent conductive oxide is used. Thus, the fabrication cost of the dye-sensitized solar cell may be reduced, as well as, the transmittance loss of incident light may be minimized.

Also, the upper electrode layer and the lower electrode layer constituting the electron circulation system of the dye-sensitized solar cell are disposed below the photovoltaic conversion part, and the supporter formed of the pore insulation material is disposed between the upper and lower electrode layers. The supporter may contribute to the prevention of the electrical short, which may result from various reasons, between the upper and lower electrodes.

The above-disclosed subject matter is to be considered illustrative, and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A dye-sensitized solar cell, comprising:
a photovoltaic conversion part disposed between a lower electrode layer and a light receiving substrate;
an upper electrode layer having through-holes, the upper electrode layer being disposed between the lower electrode layer and the photovoltaic conversion part;
a catalytic layer covering a top surface of the lower electrode layer, the catalytic layer being disposed between the lower and upper electrode layers; and
an electrolyte solution disposed between the catalytic layer and the light receiving substrate.

2. The dye-sensitized solar cell of claim 1, wherein the upper electrode layer comprises a metal foil having a uniform thickness in a region except the through-holes.

3. The dye-sensitized solar cell of claim 2, wherein the upper electrode layer further comprises at least one protrusion extending from at least one of a top surface and a bottom surface thereof.

4. The dye-sensitized solar cell of claim 1, wherein a minimum distance between the through-holes is greater than a minimum width of the through-holes.

5. The dye-sensitized solar cell of claim 1, further comprising an insulating supporter disposed between the lower electrode layer and the light receiving substrate.

6. The dye-sensitized solar cell of claim 5, wherein the insulating supporter comprises a pore layer, and the electrolyte solution is impregnated into the insulating supporter.

7. The dye-sensitized solar cell of claim 5, wherein the insulating supporter is disposed on at least one of positions between the catalytic layer and the upper electrode layer and between the upper electrode layer and the light receiving substrate.

8. The dye-sensitized solar cell of claim 1, further comprising:
a lower sealant disposed on an edge of the top surface of the lower electrode layer; and
an upper sealant disposed on an edge of a top surface of the upper electrode layer,
wherein the through-holes are formed within the upper electrode layer except a region between the lower sealant and the upper sealant.

9. The dye-sensitized solar cell of claim 1, wherein the light receiving substrate is formed of only a non-conductive material.

10. The dye-sensitized solar cell of claim 1, wherein the upper electrode layer comprises at least one of a sintered structure in which powders are connected to each other, a pore metallic material, and a conductive layer comprising a nanotube.

11. A method of fabricating a dye-sensitized solar cell, the method comprising:
preparing an upper electrode layer in which through-holes are formed;
disposing the upper electrode layer having the through-holes on a lower electrode layer;
forming a photovoltaic conversion part on the upper electrode layer;
forming a light receiving substrate on the photovoltaic conversion part; and
injecting an electrolyte solution between the light receiving substrate and the lower electrode layer.

12. The method of claim 11, wherein the preparing of the upper electrode layer in which the through-holes are formed comprises:
preparing a metal foil; and
etching the metal foil using an etching mask having openings,
wherein positions of the through-holes are defined by the openings of the etching mask.

13. The method of claim 12, wherein the etching of the metal foil comprises wet-etching at least one of a top surface and a bottom surface of the metal foil.

14. The method of claim 11, wherein the through holes are formed in the upper electrode layer before the upper electrode layer is attached to the lower electrode layer.

15. The method of claim 11, wherein at least one of the lower electrode layer and the upper electrode layer is formed using a roll-to-roll process.

16. The method of claim 11, further comprising forming an insulating supporter between the lower electrode layer and the light receiving substrate before the electrolyte solution is injected,
wherein the insulating supporter is formed using a roll-to-roll process.

17. The method of claim 16, wherein the insulating supporter comprises a pore layer, and the electrolyte solution is impregnated into the insulating supporter.

18. The method of claim 17, wherein the insulating supporter is disposed on at least one of positions between the catalytic layer and the upper electrode layer and between the upper electrode layer and the light receiving substrate.

19. The method of claim 11, wherein the light receiving substrate is formed of only a non-conductive material.

20. The method of claim 11, further comprising:
forming a catalytic layer on a top surface of the lower electrode layer before the upper electrode layer is attached on the lower electrode layer;
forming a lower sealant on an edge of a top surface of the catalytic layer, the lower sealant being formed to separate the upper electrode layer from the lower electrode layer; and
forming an upper sealant on an edge of a top surface of the upper electrode layer, the upper sealant being formed to separate the light receiving substrate from the upper electrode layer,
wherein the through-holes are formed within the upper electrode layer except a region between the lower sealant and the upper sealant.

21. The method of claim 11, wherein the forming of the photovoltaic conversion part on the upper electrode layer is performed before or after the upper electrode layer is disposed on the lower electrode layer.
